(19) United States
(12) Patent Application Publication
(10) Pub. No.: US 2023/0416605 A1
(43) Pub. Date: Dec. 28, 2023

(54) CHEMICAL LIQUID AND TREATMENT METHOD

(71) Applicant: FUJIFILM Corporation, Tokyo (JP)

(72) Inventors: Yuta SHIGENOI, HAIBARA-GUN (JP); Atsushi MIZUTANI, Haibara-gun (JP); Tomonori TAKAHASHI, Haibara-gun (JP)

(73) Assignee: FUJIFILM Corporation, Tokyo (JP)

(21) Appl. No.: 18/462,804

(22) Filed: Sep. 7, 2023

Related U.S. Application Data
(63) Continuation of application No. PCT/JP2022/003290, filed on Jan. 28, 2022.

(30) Foreign Application Priority Data
Mar. 11, 2021 (JP) 2021-039591
Sep. 12, 2021 (JP) 2021-199807

(51) Int. Cl. C09K 13/00; H01L 21/311; H01L 21/3213

(52) U.S. Cl. CPC C09K 13/00; H01L 21/31111; H01L 21/32134

(57) ABSTRACT

Provided is a chemical liquid that has an excellent etching ability for an Al oxide on a substrate and excellent etching selectivity between Al oxide and a specific metal oxide. Also provided is a treatment method using the chemical liquid. The chemical liquid contains at least one hydroxy acid selected from the group consisting of a hydroxy acid and a salt thereof, a quaternary ammonium compound, a trialkylamine, and water, and is alkaline.

### CROSS-REFERENCE TO RELATED APPLICATIONS

This application is a Continuation of PCT International Application No. PCT/JP2022/003290 filed on Jan. 28, 2022, which claims priority under 35 U.S.C. § 119(a) to Japanese Patent Application No. 2021-039591 filed on Mar. 11, 2021 and Japanese Patent Application No. 2021-199807 filed on Dec. 9, 2021. The above applications are hereby expressly incorporated by reference, in their entirety, into the present application.

### BACKGROUND OF THE INVENTION

### 1. Field of the Invention

The present invention relates to a chemical liquid and a treatment method.

### 2. Description of the Related Art

As the miniaturization of semiconductor products progresses, there is an increasing demand for performing a step of removing unnecessary transition metal-containing substances on a substrate in a semiconductor product manufacturing process with high efficiency and high accuracy.

For example, as a step of removing an unnecessary Al-containing metal oxide (hereinafter, also called “Al oxide”) on a substrate, for example, a method is widely known in which etching or removal of foreign substances attached to a solid surface is performed using a chemical liquid dissolving the unnecessary Al oxide.

For example, JP2011-094100A discloses “a chemical liquid for cleaning that is for removing plasma etching residues and/or ashing residues formed on a substrate for semiconductors, the chemical liquid containing (component a) water, (component b) hydroxylamine and/or a salt thereof, (component c) a basic organic compound, and (component d) an organic acid and having a pH of 7 to 9.”

### SUMMARY OF THE INVENTION

As a result of investigating the chemical liquid described in JP2011-094100A and the like, the inventors of the present invention have found that the chemical liquid is poor in at least either an etching ability for unnecessary Al oxide on a substrate or etching selectivity. The etching selectivity means an ability to selectively etch a compound which is a removal target in a case where an object to be treated is treated with the chemical liquid. More specifically, the etching selectivity means that in a case where Al oxide is removed, the ratio of an etching ability for Al oxide as a removal target to an etching ability for a specific metal oxide not being a removal target (etching ability for Al oxide/etching ability for specific metal oxide) is high (for example, higher than 1). The specific metal oxide is a metal oxide containing at least one element selected from the group consisting of Zn, Hf, and In.

An object of the present invention is to provide a chemical liquid that has an excellent etching ability for Al oxide on a substrate and excellent etching selectivity between Al oxide and a specific metal oxide.

Another object of the present invention is to provide a treatment method using the aforementioned chemical liquid.

In order to achieve the above objects, the inventors of the present invention carried out intensive examinations. As a result, the inventors have found that the objects can be achieved by the following constitution.

[1]

A chemical liquid containing at least one hydroxy acid selected from the group consisting of a hydroxy acid and a salt thereof, a quaternary ammonium compound, a trialkylamine, and water,
in which the chemical liquid is alkaline.

[2]

The chemical liquid described in [1], in which a content of the trialkylamine is 100 ppt by mass to 200 ppm by mass with respect to a total mass of the chemical liquid.

[3]

The chemical liquid described in [1] or [2], in which a content of the trialkylamine is 100 ppt by mass to 100 ppm by mass with respect to a total mass of the chemical liquid.

[4]

The chemical liquid described in any one of [1] to [3], in which a mass ratio of a content of the trialkylamine to a content of the hydroxy acids is 1.0×10⁻⁸ to 0.1.

[5]

The chemical liquid described in any one of [1] to [4], in which a mass ratio of a content of the trialkylamine to a content of the hydroxy acids is 1.0×10⁻⁸ to 0.01.

[6]

The chemical liquid described in any one of [1] to [5], further containing at least one metal component selected from the group consisting of Co and Ti.

[7]

The chemical liquid described in [6], in which a content of the metal component is 0.1 ppt by mass to 0.1 ppm by mass with respect to a total mass of the chemical liquid.

[8]

The chemical liquid described in [6] or [7], in which a mass ratio of a content of the metal component to a content of the trialkylamine is 1.0×10⁻⁸ to 1.0.

[9]

The chemical liquid described in any one of [6] to [8], in which a mass ratio of a content of the metal component to a content of the trialkylamine is 1.0×10⁻⁶ to 0.1.

[10]

The chemical liquid described in any one of [1] to [9], in which the hydroxy acids include at least one compound selected from the group consisting of citric acid, lactic acid, tartaric acid, glyceric acid, and salts thereof.

[11]

The chemical liquid described in any one of [1] to [10], in which a content of the hydroxy acids is 0.01 to 0.20 mol/L per 1 L of the chemical liquid.

[12]

The chemical liquid described in any one of [1] to [11], in which a pH of the chemical liquid is 7.5 to 14.0.

[13]

The chemical liquid described in any one of [1] to [12], in which a pH of the chemical liquid is 11.0 to 13.0.

[14]

The chemical liquid described in any one of [1] to [13], in which the quaternary ammonium compound includes at least one compound selected from the group consisting of tetramethylammonium hydroxide, ethyltrimethylammonium hydroxide, diethyldimethylammonium hydroxide, triethylmethylammonium hydroxide, tetraethylammonium hydroxide, and tetrabutylammonium hydroxide.

[15]

The chemical liquid described in any one of [1] to [14], further containing a nitrogen-containing aromatic ring compound.

[16]

The chemical liquid described in any one of [1] to [15], further containing an alkanolamine.

[17]

The chemical liquid described in any one of [1] to [16], further containing at least one compound selected from the group consisting of hydroxyamine, diethylhydroxyamine, ascorbic acid, pyrocatechol, and pyrogallol.

[18]

The chemical liquid described in any one of [1] to [17], further containing a tertiary amine other than the trialkylamine.

[19]

The chemical liquid described in any one of [1] to [18], in which the chemical liquid is used for an object to be treated having a substrate, an Al-containing metal oxide that is disposed on the substrate, and a metal oxide that is disposed on the substrate and contains at least one element selected from the group consisting of Zn, Hf, and In.

[20]

The chemical liquid described in any one of [1] to [19], in which the chemical liquid is used as an etchant.

[21]

A treatment method having a step of bringing the chemical liquid described in any one of [1] to [20] into contact with an object to be treated having a substrate, an Al-containing metal oxide that is disposed on the substrate, and a metal oxide that is disposed on the substrate and contains at least one element selected from the group consisting of Zn, Hf, and In.

[22]

The treatment method described in [21], in which a temperature of the chemical liquid is 40° C. to 80° C.

According to the present invention, it is possible to provide a chemical liquid that has an excellent etching ability for Al oxide on a substrate and excellent etching selectivity between Al oxide and a specific metal oxide.

Furthermore, according to the present invention, it is possible to provide a substrate treatment method using the chemical liquid.

### DESCRIPTION OF THE PREFERRED EMBODIMENTS

Hereinafter, the present invention will be specifically described.

The following constituents will be described based on typical embodiments of the present invention in some cases, but the present invention is not limited to the embodiments.

The meaning of each description in the present specification is as below.

A range of numerical values described using “to” means a range including the numerical values listed before and after “to” as the lower limit and the upper limit.

“Preparation” includes the preparation of a specific material by synthesis, mixing, or the like and the preparation of a predetermined substance by purchase or the like.

In a case where there are two or more components corresponding to a certain component, unless otherwise specified, “content” of such a component means the total content of the two or more components.

“Main component” means a component of the highest content.

“ppm” means parts-per-million (10⁻⁶). “ppb” means parts-per-billion (10⁻⁹). “ppt” means parts-per-trillion (10⁻¹²).

“Radiation” means the bright line spectrum of a mercury lamp, far ultraviolet rays represented by an excimer laser, extreme ultraviolet rays (EUV light), X-rays, or electron beams.

“Light” means an actinic ray or radiation.

Unless otherwise specified, “exposure” includes exposure to a bright line spectrum of a mercury lamp, far ultraviolet rays represented by an excimer laser, X-rays, or EUV light and exposure to particle beams such as electron beams or ion beams.

In a case where “substituted” or “unsubstituted” is not added to the notation of “group (atomic group)”, unless otherwise specified, the “group” includes a group having no substituent and a group having a substituent. For example, the notation of “hydrocarbon group” includes a hydrocarbon group having no substituent (unsubstituted hydrocarbon group) and a hydrocarbon group having a substituent (substituted hydrocarbon group). The same is true of each compound.

Regarding the description of a compound, unless otherwise specified, the compound may include isomers (compounds having the same number of atoms but different structures), optical isomers, and isotopes. In addition, a compound may include one isomer and one isotope or two or more isomers and isotopes.

Regarding the bonding direction of a divalent group (for example, —COO—), in a case where Y in a compound represented by “X—Y—Z” is —COO—, unless otherwise specified, the compound may be either “X—O—CO—Z” or “X—CO—O—Z”.

[Chemical Liquid]

The chemical liquid contains at least one hydroxy acid selected from the group consisting of a hydroxy acid and a salt thereof, a quaternary ammonium compound, a trialkylamine, and water, and is alkaline.

The mechanism through which the chemical liquid having the above composition achieves the above objects is unclear. According to the inventors of the present invention, the mechanism is considered to be as below.

Presumably, in the alkaline chemical liquid, the quaternary ammonium compound and the trialkylamine may improve the etching ability for Al oxide whereas the hydroxy acids may hinder the etching ability for a specific metal oxide, which may allow the chemical liquid to have an excellent etching ability for the Al oxide on a substrate and have an excellent etching selectivity between the Al oxide and the specific metal oxide.

Hereinafter, further improving at least one of an effect which is an etching ability for Al oxide on a substrate or an effect which is etching selectivity between Al oxide and a specific metal oxide will be also described as further improving the effect of the present invention.

[Components]

Hereinafter, the components that can be contained in the chemical liquid will be specifically described.

<Hydroxy Acids>

The chemical liquid contains hydroxy acids.

The hydroxy acids are at least one acid selected from the group consisting of a hydroxy acid and salts thereof “Hydroxy acid” means a compound having one or more hydroxy groups and one or more carboxy groups in a molecule.

The number of hydroxy groups that the hydroxy acids have is 1 or more, preferably 1 to 3, and more preferably 1 or 2.

The number of carboxy groups that the hydroxy acids have is 1 or more, preferably 1 to 5, and more preferably 1 to 3.

The total number of hydroxy groups and carboxy groups that the hydroxy acids have is 2 or more, preferably 2 to 6, and more preferably 2 to 4.

As the hydroxy acids, a compound represented by Formula (H) is preferable, and a compound represented by Formula (H1) is more preferable.

HO-L¹-COOH (H)

In Formula (H), L¹ represents a divalent linking group.

Examples of the divalent linking group include an ether group, a carbonyl group, an ester group, a thioether group, —SO₂—, -NT-, a divalent hydrocarbon group (for example, an alkylene group, an alkenylene group, an alkynylene group, and an arylene group), and a group obtained by combining these. T represents a hydrogen atom or a substituent.

The divalent linking group may further have a substituent.

Examples of the substituent include an alkyl group, an aryl group, a hydroxy group, a carboxy group, an amino group, a halogen atom, and a group which is obtained by combining these. Among these, a hydroxy group, a carboxy group, an alkyl group having a hydroxy group, or an alkyl group having a carboxy group is preferable.

As L¹, among these, a divalent hydrocarbon group is preferable, and an alkylene group which may have a substituent is more preferable.

The number of substituents that the divalent linking group has is preferably 0 to 5, and more preferably 1 to 3.

The divalent linking group preferably has 1 to 15 carbon atoms, more preferably has 1 to 10 carbon atoms, and even more preferably has 1 to 5 carbon atoms.

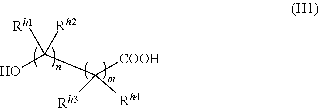

In Formula (H1), R^{h1} represents a hydroxy group, a carboxy group, an alkyl group which may have a hydroxy group, or an alkyl group which may have a carboxy group. R^{h2} to R^{h4} each independently represent a hydrogen atom, a hydroxy group, a carboxy group, an alkyl group which may have a hydroxy group, or an alkyl group which may have a carboxy group. n represents an integer of 1 to 3. m represents an integer of 0 to 3.

The alkyl group may be linear, branched, or cyclic, and is preferably linear.

The number of carbon atoms of the alkyl group is preferably 1 to 10, more preferably 1 to 5, even more preferably 1 to 3, and particularly preferably 1 or 2.

R^{h1} is preferably a carboxy group, an alkyl group which may have a hydroxy group, or an alkyl group which may have a carboxy group.

R^{h2} is preferably a hydrogen atom, a hydroxy group, or a carboxy group, and more preferably a hydrogen atom or a carboxy group.

R^{h3} and R^{h4} are preferably a hydrogen atom, a hydroxy group, a carboxy group, or an alkyl group which may have a carboxy group, more preferably a hydrogen atom, a hydroxy group, or a carboxy group, and even more preferably a hydrogen atom.

The total number of hydroxy groups that R^{h1} to R^{h4} have is preferably 0 to 2, and more preferably 0 or 1.

The number of carboxy groups that R^{h1} to R^{h4} have is preferably 0 to 4, more preferably 0 to 2, and even more preferably 1.

The total number of hydroxy groups and carboxy groups that R^{h1} to R^{h4} have is preferably 0 to 4, and more preferably 0 to 2.

A plurality of R^{h1}'s, R^{h2}'s, R^{h3}'s, and R^{h4}'s may be the same as or different from each other.
n represents an integer of 1 to 3. m represents an integer of 0 to 3.
n is preferably 1 or 2, and more preferably 1. m is preferably 0 to 2, and more preferably 0 or 1.

Examples of the hydroxy acids include an aliphatic hydroxy acid, an aromatic hydroxy acid, and salts thereof.

Examples of the aliphatic hydroxy acid and salts thereof include citric acid, lactic acid, tartaric acid, glyceric acid, glycolic acid, tartronic acid, leucic acid, malic acid, gluconic acid, isocitric acid, mevalonic acid, pantoic acid, hydroxypentanoic acid, hydroxyhexanoic acid, hydroxyethyliminodiacetic acid, hydroxyiminodisuccinic acid, quinic acid, and salts thereof.

Examples of the aromatic hydroxy acid and salts thereof include salicylic acid, 4-hydroxyphthalic acid, 4-hydroxyisophthalic acid, cresotic acid, vanillic acid, syringic acid, resorcylic acid, protocatechuic acid, gentisic acid, orsellinic acid, gallic acid, mandelic acid, atrolactic acid, melilotic acid, phloretic acid, coumaric acid, umbellic acid, caffeic acid, and salts thereof.

The hydroxy acids may be amino acids having a hydroxyl group.

Examples thereof include serine, threonine, tyrosine, hydroxyproline, hydroxylysine, homoserine, allothreonine, N-acyl-N-(2-hydroxyethyl)-β-alanine, and salts thereof.

Among these, the hydroxy acids preferably include an aliphatic hydroxy acid and salts thereof, more preferably include at least one compound selected from the group consisting of citric acid, lactic acid, tartaric acid, glyceric acid, glycolic acid, and salts thereof, even more preferably include at least one compound selected from the group consisting of citric acid, lactic acid, tartaric acid, glyceric acid, and salts thereof, and particularly preferably include citric acid and salts thereof.

Examples of salts of the hydroxy acid include metal salts which are preferably salts of alkali metals such as sodium and potassium and salts of alkaline earth metals such as calcium and magnesium.

The molecular weight of the hydroxy acids is preferably 30 to 3,000, more preferably 50 to 1,000, and even more preferably 50 to 300.

One kind of hydroxy acids or two or more kinds of hydroxy acids may be used.

The content of the hydroxy acids is preferably 0.0001 to 1.00 mol/L per 1 L of the chemical liquid. In view of further improving the effect of the present invention, the content of the hydroxy acids is more preferably 0.001 to 0.20 mol/L, and even more preferably 0.01 to 0.20 mol/L.

<Quaternary Ammonium Compound>

The chemical liquid contains a quaternary ammonium compound.

Examples of the quaternary ammonium compound include a compound having one quaternary ammonium cation in a molecule and a salt thereof.

The quaternary ammonium compound is not particularly limited as long as it is a compound having one quaternary ammonium cation in which a nitrogen atom is substituted with four hydrocarbon groups, or a salt thereof.

The hydrocarbon groups are preferably alkyl groups or aryl groups.

Examples of the quaternary ammonium compound include quaternary ammonium hydroxide, quaternary ammonium fluoride, quaternary ammonium bromide, quaternary ammonium iodide, quaternary ammonium acetate, and quaternary ammonium carbonate.

The quaternary ammonium compound is preferably a quaternary ammonium hydroxide, and more preferably a compound represented by Formula (A).

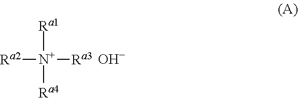

In Formula (A), R^{a1} to R^{a4} each independently represent an alkyl group having 1 to 16 carbon atoms, an aryl group having 6 to 16 carbon atoms, an aralkyl group having 7 to 16 carbon atoms, or an alkyl group having 1 to 16 carbon atoms with a hydroxy group. At least two out of R^{a1} to R^{a4} may be bonded to each other to form a cyclic structure.

The alkyl group may be linear, branched, or cyclic.

The number of carbon atoms in the alkyl group is preferably 1 to 10, more preferably 1 to 5, and even more preferably 1 to 4.

In view of ease of availability, examples of the quaternary ammonium compound include tetramethylammonium hydroxide (TMAH), tetraethylammonium hydroxide (TEAH), tetrapropylammonium hydroxide, tetrabutylammonium hydroxide (TBAH), methyltripropylammonium hydroxide, methyltributylammonium hydroxide, diethyldimethylammonium hydroxide (DEDMAH), triethylmethylammonium hydroxide (TEMAH), ethyltrimethylammonium hydroxide (ETMAH), dimethyldiethylammonium hydroxide, benzyltrimethylammonium hydroxide (BzTMAH), hexadecyltrimethylammonium hydroxide, (2-hydroxyethyl)trimethylammonium, and spiro-(1,1′)-bipyrrolidinium hydroxide.

Among these, the quaternary ammonium compound preferably includes at least one compound selected from the group consisting of tetramethylammonium hydroxide, ethyltrimethylammonium hydroxide, diethyldimethylammonium hydroxide, triethylmethylammonium hydroxide, tetraethylammonium hydroxide, and tetrabutylammonium hydroxide.

One quaternary ammonium compound or two or more quaternary ammonium compounds may be used.

The content of the quaternary ammonium compound with respect to the total mass of the chemical liquid is preferably 0.1% by mass or more, and more preferably 0.5% by mass or more. The upper limit of the content of the pH adjuster is preferably 20.0% by mass or less with respect to the total mass of the chemical liquid.

It is also preferable to adjust the content of the quaternary ammonium compound such that the pH of the chemical liquid that will be described later falls into a suitable range.

<Trialkylamine>

The chemical liquid contains a trialkylamine.

Trialkylamine is a tertiary amino group-containing compound formed by the substitution of a nitrogen atom with three alkyl groups.

As the trialkylamine, a compound represented by Formula (B) is preferable.

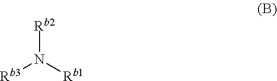

In Formula (B), R^{b1} to R^{b3} each independently represent an alkyl group.

The alkyl group may be linear, branched, or cyclic.

The number of carbon atoms of the alkyl group is preferably 1 to 30, more preferably 1 to 20, even more preferably 1 to 10, still more preferably 1 to 5, and particularly preferably 1 or 2.

It is preferable that at least two out of R^{b1} to R^{b3} be the same groups. It is more preferable that all of R^{b1} to R^{b3} be the same groups.

At least two out of R^{b1} to R^{b3} may be bonded to each other to form a cyclic structure.

Examples of the trialkylamine include trimethylamine, triethylamine, tripropylamine, tributylamine, dimethylethylamine, dimethylpropylamine, dimethylbutylamine, diethylmethylamine, diethylpropylamine, diethylbutylamine, dipropylmethylamine, dipropylethylamine, dipropylbutylamine, dibutylmethylamine, dibutylethylamine, and dibutylpropylamine.

Among these, at least one compound selected from the group consisting of trimethylamine, diethylmethylamine, triethylamine, and tributylamine is preferable, and trimethylamine is more preferable.

One trialkylamine or two or more trialkylamines may be used.

The content of the trialkylamine is preferably 1 ppt by mass to 1,000 ppm by mass with respect to the total mass of the chemical liquid. In view of further improving the effect of the present invention, the content of the trialkylamine is more preferably 100 ppt by mass to 200 ppm by mass, and even more preferably 100 ppt by mass to 100 ppm by mass. The mass ratio of the content of the trialkylamine to the content of the hydroxy acids (content of trialkylamine/content of hydroxy acids) is preferably 1.0×10⁻¹⁰ to 1.0. The mass ratio is more preferably 1.0×10⁻⁸ to 0.1 in view of further improving the effect of the present invention, and even more preferably 1.0×10⁻⁸ to 0.01 in view of further improving defect suppressiveness.

<Water>

The chemical liquid contains water.

Examples of the water include ultrapure water used for manufacturing semiconductor devices.

The water is preferably water in which the content of inorganic anions, metal ions, or the like is reduced, more preferably water in which the concentration of ions derived from metal atoms of Fe, Co, Na, K, Ca, Cu, Mg, Mn, Li, Al, Cr, Ni, and Zn is reduced, and even more preferably water in which the content of inorganic anions, metal ions, or the like is adjusted in the order of ppt by mass or less (for example, the content of metals is less than 0.001 ppt by mass) in a case where the water is used for preparing the chemical liquid.

Examples of the adjusting method include the method described in paragraphs “0074” to “0084” of JP2011-110515A and the methods described in JP2007-254168A. As the adjusting method, purification or distillation purification using a filtration membrane or an ion-exchange membrane is preferable.

As the water used in the embodiment of the present invention, the water obtained as above is preferable.

It is preferable that the water be also used for cleaning the container that will be described later. It is also preferable that the water be also in the manufacturing process of the chemical liquid, the measurement of components of the chemical liquid, and the measurement for evaluating the chemical liquid.

The content of water with respect to the total mass of the chemical liquid is preferably 50% by mass or more, more preferably 65% by mass or more, and even more preferably 70% by mass or more. The upper limit of the content of water with respect to the total mass of the chemical liquid is preferably 99.99% by mass or less, and more preferably 99.9% by mass or less.

<pH>

The chemical liquid is alkaline.

The pH of the chemical liquid is preferably more than 7.0 and 14.0 or less. In view of further improving the effect of the present invention, the pH is more preferably 7.5 to 14.0, even more preferably 8.5 to 13.5, still more preferably 11.0 to 13.0, and particularly preferably 11.5 to 12.5.

The pH of the chemical liquid is a value obtained by measuring pH of the chemical liquid at 25° C. by using a known pH meter.

<Optional Components>

The chemical liquid may further contain an optional component in addition to the above components.

Hereinafter, optional components that can be contained in the chemical liquid will be specifically described.

It is preferable that the chemical liquid contain at least one compound selected from the group consisting of hydroxyamine, diethylhydroxyamine, ascorbic acid, pyrocatechol, and pyrogallol.

(Co and Ti)

The chemical liquid may contain at least one metal component (hereinafter, also called “specific metal component”) selected from the group consisting of Co (cobalt) and Ti (titanium).

The specific metal component may be either metal particles or metal ions.

The chemical liquid may contain either or both of metal particles and metal ions as the specific metal component.

The metal particles as the specific metal component may be either a simple metal or an alloy, or may be in the form of an aggregate composed of a metal and an organic substance.

The specific metal component may be any of a specific metal component that is inevitably incorporated into each component (raw material) contained in the chemical liquid, a specific metal component that is inevitably incorporated during the manufacturing, storage, and/or transfer of the chemical liquid, and a specific metal component that is intentionally added.

One specific metal component may be used alone, or two or more specific metal components may be used.

In a case where the chemical liquid contains a specific metal component, the content of the specific metal component with respect to the total mass of the chemical liquid is preferably 0.01 ppt by mass to 10 ppm by mass, and more preferably 0.1 ppt by mass to 0.1 ppm by mass.

“Content of the specific metal component” means the total content of metal particles as the specific metal component and metal ions as the specific metal component.

In a case where the chemical liquid contains a metal component containing Co (hereinafter, also called “Co metal component”), the content of the Co metal component with respect to the total mass of the chemical liquid is preferably 1,000 ppt by mass or less, more preferably 100 ppt by mass or less, and even more preferably 1 ppt by mass or less. The upper limit of the content of the Co metal component with respect to the total mass of the chemical liquid is preferably 0 ppt by mass or more, more preferably more than 0 ppt by mass, and even more preferably 0.01 ppt by mass or more.

In a case where the chemical liquid contains a metal component containing Ti (hereinafter, also called “Ti metal component”), the content of the Ti metal component with respect to the total mass of the chemical liquid is preferably 100 ppm by mass or less, more preferably 1 ppm by mass or less, and even more preferably 0.1 ppm by mass or less. The upper limit of the content of the Ti metal component with respect to the total mass of the chemical liquid is preferably 0 ppt by mass or more, more preferably more than 0 ppt by mass, and even more preferably 0.01 ppt by mass or more.

The mass ratio of the content of the specific metal component to the content of the trialkylamine (content of specific metal component/content of trialkylamine) is preferably 1.0×10⁻⁸ to 10.0. In view of further improving the effect of the present invention, the mass ratio is more preferably 1.0×10⁻⁸ to 1.0 in view of further improving the effect of the present invention, even more preferably 1.0×10⁻⁶ to 0.1 in view of further improving defect suppressiveness, and particularly preferably 1.0×10⁻⁸ to 0.01.

The type and content of the specific metal component can be measured by single nano particle inductively coupled plasma mass spectrometry (SP-ICP-MS).

“SP-ICP-MS” and inductively coupled plasma mass spectrometry (ICP-MS) use the same device. The only difference between SP-ICP-MS and ICP-MS is how to analyze data. With SP-ICP-MS, data can be analyzed using commercial software.

With ICP-MS, the content of the specific metal component as a measurement target is measured regardless of the way the metal component is present. Accordingly, the total mass of metal particles and metal ions as the specific metal component that is a measurement target is quantified as the content of the specific metal component.

Examples of the method of adjusting the content of the specific metal component include a method of performing a known treatment for removing the specific metal from the chemical liquid, a method of performing a known treatment for removing the specific metal from the raw material containing each component used for preparing the chemical liquid, a method of adding a compound containing metal ions as the specific metal component to the chemical liquid, and the like.

The chemical liquid may contain other metal components in addition to the specific metal component.

Examples of those other metal components include a transition metal component other than the specific metal component.

(Organic Solvent)

The chemical liquid may contain an organic solvent.

As the organic solvent, a hydrophilic organic solvent is preferable.

“Hydrophilic organic solvent” means an organic solvent that dissolves in an amount of 0.1 g or more in 100 g of water under the condition of 25° C.

The hydrophilic organic solvent is preferably an organic solvent that can be uniformly mixed with water at any mixing ratio.

Examples of the hydrophilic organic solvent include a glycol-based solvent, a glycol ether-based solvent, an amide-based solvent, an alcohol-based solvent, and a sulfoxide-based solvent.

Examples of the glycol-based solvent include ethylene glycol, propylene glycol, diethylene glycol, dipropylene glycol, triethylene glycol, and tetraethylene glycol.

Examples of the glycol ether-based solvent include glycol monoether.

Examples of the glycol monoether include ethylene glycol monomethyl ether, ethylene glycol monoethyl ether, ethylene glycol mono-n-propyl ether, ethylene glycol monoisopropyl ether, ethylene glycol mono-n-butyl ether, diethylene glycol monomethyl ether, diethylene glycol monoethyl ether, diethylene glycol monobutyl ether, triethylene glycol monomethyl ether, triethylene glycol monoethyl ether, triethylene glycol monobutyl ether, 1-methoxy-2-propanol, 2-methoxy-1-propanol, 1-ethoxy-2-propanol, 2-ethoxy-1-propanol, propylene glycol mono-n-propyl ether, dipropylene glycol monomethyl ether, dipropylene glycol monoethyl ether, dipropylene glycol mono-n-propyl ether, tripropylene glycol monoethyl ether, tripropylene glycol monomethyl ether, ethylene glycol monobenzyl ether, and diethylene glycol monobenzyl ether.

Examples of the amide-based solvent include N,N-dimethylformamide, 1-methyl-2-pyrrolidone, 2-pyrrolidinone, 1,3-dimethyl-2-imidazolidinone, formamide, N-methylformamide, acetamide, N-methylacetamide, N,N-dimethylacetamide, N-methylpropanamide, and hexamethylphosphoric triamide.

Examples of the alcohol-based solvent include alkanediol, alkoxyalcohol, saturated aliphatic monohydric alcohol, and unsaturated non-aromatic monohydric alcohol.

Examples of the alkanediol include glycol, 2-methyl-1,3-propanediol, 1,3-propanediol, 2,2-dimethyl-1,3-propanediol, 1,4-butanediol, 1,3-butanediol, 1,2-butanediol, 2,3-butanediol, and pinacol.

Examples of the alkoxy alcohol include 3-methoxy-3-methyl-1-butanol, 3-methoxy-1-butanol, and 1-methoxy-2-butanol.

Examples of the saturated aliphatic monohydric alcohol include methanol, ethanol, n-propyl alcohol, isopropanol (isopropyl alcohol), 1-butanol, 2-butanol, isobutyl alcohol, tert-butyl alcohol, 2-pentanol, t-pentyl alcohol, and 1-hexanol.

Examples of the unsaturated non-aromatic monohydric alcohol include allyl alcohol, propargyl alcohol, 2-butenyl alcohol, 3-butenyl alcohol, and 4-penten-2-ol.

Examples of low-molecular-weight alcohol having a ring structure include tetrahydrofurfuryl alcohol, furfuryl alcohol, and 1,3-cyclopentanediol.

Examples of the sulfoxide-based solvent include dimethyl sulfoxide.

One organic solvent or two or more organic solvents may be used.

The content of the organic solvent with respect to the total mass of the chemical liquid is preferably 0.001% to 10% by mass, and more preferably 0.01% to 3% by mass.

(Basic Compound)

The chemical liquid may contain a basic compound.

“Basic compound” means a compound having a pH more than 7 in a case where the compound is made into a solution by being dissolved in water.

The basic compound has a function of removing residues such as etching residues and ashing residues. The basic compound also functions as a pH adjuster for adjusting the pH of the chemical liquid.

Examples of the basic compound include ammonium hydroxide (NH₄OH) and an amine compound.

In a case where the chemical liquid contains ammonium hydroxide, the content of the ammonium hydroxide with respect to the total mass of the chemical liquid is preferably 0.01% to 10% by mass, and more preferably 0.05% to 5% by mass.

The amine compound is a compound that has an amino group in the molecule.

The quaternary ammonium compound and the trialkylamine are not included in the basic compound.

Examples of the amine compound include a primary amine having a primary amino group (—NH₂) in the molecule, a secondary amine having a secondary amino group (>NH) in the molecule, a tertiary amine having a tertiary amino group (>N—) in the molecule, and a salt of these.

Examples of the salt of the amine compound include a salt with an inorganic acid formed by the bonding of at least one non-metal selected from the group consisting of Cl, S, N, and P to hydrogen. As such a salt, a hydrochloride, a sulfate, or a nitrate is preferable.

The amine compound is preferably a water-soluble amine capable of dissolving in an amount of 50 g or more in 1 L of water.

Examples of the amine compound include an alicyclic amine compound, an alkanolamine, a hydroxyamine compound, and a hydrazide compound.

The alicyclic amine compound is one of the amine compounds that has an alicyclic structure in the molecule and is different from the nitrogen-containing aromatic ring compound which will be described later.

Examples of the alicyclic amine compound include 1,8-diazabicyclo[5.4.0]-7-undecene (DBU), ε-caprolactum, the following compound 1, the following compound 2, the following compound 3, 1,4-diazabicyclo[2.2.2]octane (DABCO), tetrahydrofurfurylamine, N-(2-aminoethyl)piperazine, hydroxyethyl piperazine, piperazine, 2-methylpiperazine, trans-2,5-dimethylpiperazine, cis-2,6-dimethylpiperazine, 2-piperidinemethanol, N-(2-hydroxyethylmorpholine), 4-(2-cyanoethyl)morpholine, N,N′,N″-tris(3-dimethylaminepropyl)-hexahydro-s-triazine, N-methyl-N′-(2-dimethylaminoethyl)piperazine, N,N-bis(3-aminopropylpiperazine), N-aminoethylpiperazine, cyclohexylamine, and 1,5-diazabicyclo[4,3,0]-5-nonene.

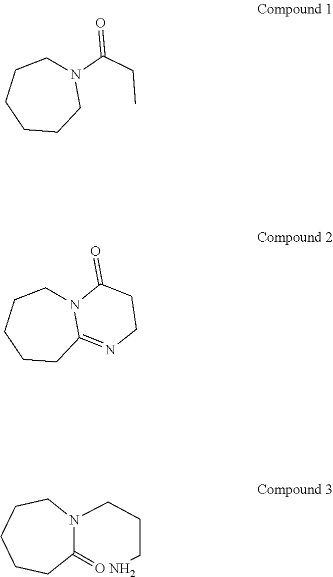

The alkanolamine is one of the amine compounds that has one or more hydroxyalkyl groups in the molecule.

The alkanolamine may have any of a primary amino group, a secondary amino group, and a tertiary amino group, and preferably has a primary amino group.

Examples of the alkanolamine include monoethanolamine (MEA), diethanolamine (DEA), triethanolamine (TEA), N-methyldiethanolamine, 2-(dimethylamino)-2-methyl-1-propanol (DMAMP), diethylene glycol amine (DEGA), trishydroxymethylaminomethane (Tris), 2-amino-2-methyl-1-propanol (AMP), 2-amino-2-methyl-1,3-dipropanol (AMPD), 2-amino-2-ethyl-1,3-dipropanol (AEPD), 2-(methylamino)-2-methyl-1-propanol (N-MAMP), N,N-dimethylaminoethoxyethanol, 1,1-((3-(dimethylamino)propylimino)-bis-2-propanol, N,N,N′-trimethylaminoethylethanolamine, a propylene oxide adduct of ethylenediamine, 2-(aminoethoxy)ethanol (AEE), and N-(2-aminoethyl)ethanolamine (AEEA). Among these, N-methyldiethanolamine, AEE, or AEEA is preferable.

The hydroxyamine compound is at least one compound selected from the group consisting of hydroxyamine (NH₂OH), a hydroxyamine derivative, and a salt of these.

The hydroxyamine compound has a function of facilitating the decomposition and solubilization of residues and removing residues such as etching residues and ashing residues.

Examples of the hydroxyamine derivative include O-methylhydroxyamine, O-ethylhydroxyamine, N-methylhydroxyamine, N,N-dimethylhydroxyamine, N,O-dimethylhydroxyamine, N-ethylhydroxyamine, N,N-diethylhydroxyamine, N,O-diethylhydroxyamine, O,N,N-trimethylhydroxyamine, N,N-dicarboxyethylhydroxyamine, and N,N-disulfoethylhydroxyamine.

Examples of salts of the hydroxyamine and the hydroxyamine derivative include an inorganic acid salt and an organic acid salt. Among these, an inorganic acid salt formed by the bonding of a non-metal atom of Cl, S, N, or P to a hydrogen atom is preferable, and a salt of any acid among hydrochloric acid, sulfuric acid, and nitric acid is more preferable.

As the inorganic acid salt of the hydroxyamine and the hydroxyamine derivative, hydroxyamine nitrate, hydroxyamine sulfate, hydroxyamine hydrochloride, hydroxyamine phosphate, N,N-diethylhydroxyamine sulfate, N,N-diethylhydroxyamine nitrate, or mixtures of these are preferable.

Examples of the organic acid salt of the hydroxyamine and the hydroxyamine derivative include hydroxyammonium citrate, hydroxyammonium oxalate, and hydroxyammonium fluoride. Among these, hydroxyamine is preferable.

The content of the hydroxyamine compound with respect to the total mass of the chemical liquid is preferably 0.01% to 30% by mass, and more preferably 0.5% to 25% by mass.

Examples of primary amines other than the alicyclic amine compound, the alkanol amine, and the hydroxyamine compound include methylamine, ethylamine, propylamine, butylamine, pentylamine, methoxyethylamine, and methoxypropylamine.

Examples of secondary amines other than the alicyclic amine compound, the alkanol amine, and the hydroxyamine compound include dimethylamine, diethylamine, dipropylamine, and dibutylamine (DBA).

The hydrazide compound means a compound in which a hydroxy group of an acid is substituted with a hydrazino group (—NH—NH₂), and a derivative thereof (a compound in which a hydrazino group is substituted with at least one substituent).

The hydrazide compound may have two or more hydrazino groups.

Examples of the hydrazide compound include carboxylic acid hydrazide and sulfonic acid hydrazide, and carbohydrazide (CHZ) is preferable.

As the basic compound, an amine compound is preferable, an alkanolamine or a hydroxyamine compound is more preferable, and a monoethanolamine or a hydroxyamine is even more preferable.

One basic compound may be used alone or two or more basic compounds may be used.

The content of the basic compound with respect to the total mass of the chemical liquid is preferably 0.01% to 30% by mass, and more preferably 0.1% to 20% by mass.

(Acidic Compound)

The chemical liquid may contain an acidic compound to adjust the pH of the chemical liquid.

The acidic compound may be either an inorganic acid or an organic acid.

The acidic compound does not include the aforementioned hydroxy acids.

Examples of the inorganic acid include sulfuric acid, hydrochloric acid, acetic acid, nitric acid, and phosphoric acid. Among these, sulfuric acid, hydrochloric acid, or acetic acid is preferable.

Examples of the organic acid include lower (with 1 to 4 carbon atoms) aliphatic monocarboxylic acids such as formic acid, acetic acid, propionic acid, and butyric acid.

In a case where an acidic compound is used such that the pH of the chemical liquid has a suitable aspect that will be described later, the type of acidic compound to be used can be appropriately selected and the content thereof can be adjusted according to the type and content of components contained in the chemical liquid.

(Nitrogen-Containing Aromatic Ring Compound)

The chemical liquid may contain a nitrogen-containing aromatic ring compound.

The nitrogen-containing aromatic ring compound is a compound having one or more aromatic rings containing a nitrogen atom in the molecule.

The aromatic ring may contain two or more nitrogen atoms.

The nitrogen-containing aromatic ring compound is a compound different from the various components described above.

As the nitrogen-containing aromatic ring compound, an azole compound is preferable.

The azole compound is a compound having one or more aromatic 5-membered rings containing a nitrogen atom.

Examples of the azole compound include an imidazole compound, a pyrazole compound, a thiazole compound, a triazole compound, and a tetrazole compound.

The azole compound may have a substituent on the aromatic 5-membered ring. Examples of the substituent include a hydroxy group, a carboxy group, a mercapto group, an amino group, an alkyl group which may have an amino group and has 1 to 4 carbon atoms, and a 2-imidazolyl group.

Examples of the imidazole compound include imidazole, 1-methylimidazole, 2-methylimidazole, 5-methylimidazole, 1,2-dimethylimidazole, 2-mercaptoimidazole, 4,5-dimethyl-2-mercaptoimidazole, 4-hydroxyimidazole, 2,2′-biimidazole, 4-imidazole carboxylic acid, histamine, benzimidazole, and a purine compound. Among these, imidazole or a purine compound is preferable.

The purine compound means a compound that includes at least one compound selected from the group consisting of purine and purine derivatives.

Examples of the purine compound include purine, adenine, guanine, hypoxanthine, xanthine, theobromine, caffeine, uric acid, isoguanine, adenosine, enprofylline, xanthosine, 7-methylxanthosine, 7-methylxanthine, theophylline, eritadenine, paraxanthine, 3-methyladenine, 3-methylxanthine, 1,7-dimethylxanthine, and 1-methylxanthine.

(Reducing Compound)

The chemical liquid may contain a reducing compound.

The reducing compound is a compound that has an oxidizing action and functions to oxidizing OH— ions or dissolved oxygen contained in the chemical liquid. The reducing compound is also called an oxygen scavenger.

The reducing compound is a compound different from the various components described above.

Examples of the reducing compound include an ascorbic acid compound, a catechol compound, and a reducing sulfur compound.

It is preferable that the reducing compound include at least one compound selected from the group consisting of ascorbic acid, pyrocatechol, and pyrogallol.

The ascorbic acid compound means at least one compound selected from the group consisting of ascorbic acid, an ascorbic acid derivative, and salts thereof.

Examples of the ascorbic acid derivative include an ascorbic acid phosphoric acid ester and an ascorbic acid sulfuric acid ester.

As the ascorbic acid compound, ascorbic acid, an ascorbic acid phosphoric acid ester, or an ascorbic acid sulfuric acid ester is preferable, and ascorbic acid is more preferable.

The catechol compound means at least one compound selected from the group consisting of pyrocatechol (benzene-1,2-diol) and a catechol derivative.

The catechol derivative means a compound in which pyrocatechol is substituted with at least one substituent. Examples of the substituent that the catechol derivative has include a hydroxy group, a carboxylic acid ester group, a sulfo group, a sulfonic acid ester group, an alkyl group, and an aryl group. The sulfo group that the catechol derivative has as a substituent may be a salt with a cation.

Examples of the catechol compound include pyrocatechol, 4-tert-butylcatechol, pyrogallol, methyl gallate, 1,2,4-benzenetriol, and tyrone.

The reducing sulfur compound is a compound that contains a sulfur atom and functions as a reducing agent.

Examples of the reducing sulfur compound include cysteine, mercaptosuccinic acid, dithiodiglycerol, bis(2,3-dihydroxypropylthio)ethylene, sodium 3-(2,3-dihydroxypropylthio)-2-methyl-propylsulfonate, 1-thioglycerol, sodium 3-mercapto-1-propanesulfonate, 2-mercaptoethanol, thioglycolic acid, and 3-mercapto-1-propanol.

As the reducing sulfur compound, a compound having a SH group (mercaptan compound) is preferable, cysteine, 1-thioglycerol, sodium 3-mercapto-1-propanesulfonate, 2-mercaptoethanol, 3-mercapto-1-propanol, or thioglycolic acid is more preferable, and cysteine is even more preferable.

One reducing compound may be used alone, or two or more reducing agents may be used.

The content of the reducing compound with respect to the total mass of the chemical liquid is preferably 0.01% to 30% by mass, and more preferably 0.01% to 20% by mass.

(Tertiary Amine Compound Other than Trialkylamine)

The chemical liquid may contain a tertiary amine compound other than the trialkylamine.

The tertiary amine compound is a compound that has a tertiary amino group and is different from the trialkylamine and various other components.

The number of tertiary amino groups that the tertiary amine compound has is preferably 1 or more, more preferably 2 or more, and even more preferably 2 to 5.

The number of nitrogen atoms that the tertiary amine compound has is preferably 1 or more, more preferably 2 or more, and even more preferably 2 to 5.

Examples of the tertiary amine compound include an aliphatic tertiary amine compound.

Some of the methylene groups (—CH₂—) in the aliphatic tertiary amine compound may be substituted with a hetero atom (for example, an oxygen atom, a sulfur atom, or the like). Examples of the tertiary amine compound include N,N,N′,N′-tetramethylethylenediamine, bis(2-dimethylaminoethyl)ether, 3-(dimethylamino)propylamine, N,N,N′,N′-tetramethylhexamethylenediamine, N,N,N′,N″,N″-pentamethyldiethylenetriamine, N,N,N′,N″,N′″,N′″-hexamethyltriethylenetetramine, and 1,3-bis(dimethylamino)butane. Among these, N,N,N′,N″,N″-pentamethyldiethylenetriamine is preferable.

(Surfactant)

The chemical liquid may contain a surfactant.

Examples of the surfactant include a compound having a hydrophilic group and a hydrophobic group (lipophilic group) in the molecule. Specific examples thereof include an anionic surfactant, a cationic surfactant, and a nonionic surfactant.

Examples of the hydrophobic group contained in the surfactant include an aliphatic hydrocarbon group, an aromatic hydrocarbon group, and a group obtained by combining these.

In a case where the hydrophobic group has an aromatic hydrocarbon group, the number of carbon atoms in the hydrophobic group is preferably 6 or more, and more preferably 10 or more. In a case where the hydrophobic group does not include an aromatic hydrocarbon group and is composed of only an aliphatic hydrocarbon group, the number of carbon atoms in the hydrophobic group is preferably 8 or more, and more preferably 10 or more. The upper limit of the number of carbon atoms is preferably 24 or less, and more preferably 20 or less.

Examples of the anionic surfactant include an anionic surfactant having at least one hydrophilic group selected from the group consisting of a sulfonic acid group, a carboxy group, a sulfuric acid ester group, and a phosphonic acid group in the molecule.

Examples of the anionic surfactant having a sulfonic acid group include alkylsulfonic acid, alkylbenzenesulfonic acid, alkylnaphthalenesulfonic acid, alkyldiphenylether sulfonic acid, fatty acid amide sulfonic acid, and a salt of these.

Examples of the anionic surfactant having a carboxy group include polyoxyethylene alkyl ether carboxylic acid, polyoxyethylene alkyl ether acetic acid, polyoxyethylene alkyl ether propionic acid, a fatty acid, and salts thereof.

Examples of the salt of the anionic surfactant include an ammonium salt, a sodium salt, a potassium salt, and a tetramethylammonium salt.

Examples of the cationic surfactant include a compound having a cationic hydrophilic group and the aforementioned hydrophobic group. Specifically, examples of the cationic surfactant include a quaternary ammonium salt-based surfactant and an alkyl pyridium-based surfactant.

One surfactant or two or more surfactants may be used.

The content of the surfactant with respect to the total mass of the chemical liquid is preferably 0.01% by mass or more, and more preferably 0.03% by mass or more. In view of suppressing foaming of the chemical liquid, the upper limit of the content of the surfactant with respect to the total mass of the chemical liquid is preferably 10% by mass or less, and more preferably 5% by mass or less.

[Physical Characteristics of Chemical Liquid]

<Coarse Particles>

It is preferable that the chemical liquid substantially do not contain coarse particles.

“Coarse particles” mean particles having a diameter of 0.2 m or more in a case where the shape of the particles is regarded as a sphere. “Substantially do not contain coarse particles” means that in a case where the chemical liquid is measured using a commercially available measuring device by a light scattering-type liquid-borne particle measuring method, the number of particles having a diameter of 0.2 m or more is 10 or less in 1 mL of the chemical liquid. The lower limit of the number of coarse particles is preferably 0 or more.

The coarse particles contained in the chemical liquid are the particles, such as dirt, dust, organic solids, and inorganic solids incorporated into the raw materials as impurities and the particles such as dirt, dust, organic solids, and inorganic solids, and the like mixed in as impurities in the process of preparing the chemical liquid that are remain as particles in the chemical liquid to the end without being dissolved.

Examples of the method of measuring the content of coarse particles include a method of measuring the content of coarse particles in a liquid phase by using a commercially available measuring device used in a light scattering-type liquid-borne particle measuring method employing a laser as a light source.

Examples of the method of removing coarse particles include a filtering treatment.

[Manufacturing Method of Chemical Liquid]

<Chemical Liquid Preparation Step>

As the manufacturing method of the chemical liquid, for example, known manufacturing methods can be used.

The manufacturing method of the chemical liquid may have a chemical liquid preparation step.

Examples of the chemical liquid preparation step include a method of preparing components such as the hydroxy acids, the quaternary ammonium compound, the trialkylamine, and the water described above and optional components and then mixing the components together to prepare the chemical liquid. In the chemical liquid preparation step, the components may be mixed together in any order without particular limitation.

The manufacturing method of the chemical liquid may have a diluting step of diluting the chemical liquid. That is, the chemical liquid may be used after being diluted with a diluent such as water.

<Filtering Step>

In order to remove foreign substances, coarse particles, and the like from the chemical liquid, the manufacturing method of the chemical liquid may have a filtering step of filtering the chemical liquid.

Examples of the filtering method include known filtering methods. Among these, filtering using a filter is preferable.

Examples of the filter used for filtering include known filters used for filtering.

Examples of materials constituting the filter include a fluororesin such as polytetrafluoroethylene (PTFE), a polyamide resin such as nylon, and a polyolefin resin such as polyethylene and polypropylene (PP) (including high-density and ultra-high-molecular-weight polyolefin resins). Among these, a polyamide resin, PTFE, or polypropylene (including high-density polypropylene) is preferable.

In a case where a filter composed of the above material is used, the foreign substances having high polarity that are likely to cause defects can be more effectively removed from the chemical liquid.

The critical surface tension of the filter is preferably 70 mN/m or more. The upper limit thereof is preferably 95 mN/m or less. Especially, the critical surface tension is more preferably 75 to 85 mN/m.

The value of the critical surface tension is a nominal value from the manufacturer.

Using a filter having a critical surface tension in the above range makes it possible to more effectively remove foreign substances having high polarity which are likely to cause defects from the chemical liquid.

The pore diameter of the filter is preferably 0.001 to 1.0 m, more preferably 0.02 to 0.5 m, and even more preferably 0.01 to 0.1 m. In a case where the pore diameter of the filter is within the above range, it is possible to remove fine foreign substances from the chemical liquid while suppressing filter clogging.

Two or more filters may be combined and used as a filter.

The filtering using a first filter may be performed once or twice or more.

In a case where filtering is performed twice or more by combining a first filter and a second filter different from the first filter, the filters may be the same as or different from each other. It is preferable that the filters be different from each other. It is preferable that at least one of the pore diameter or the constituent material vary between the first filter and the second filter.

The pore diameter for the second filtering and the subsequent filtering is preferably the same as or smaller than the pore diameter for the first filtering. Furthermore, first filters having different pore diameters within the above range of pore diameters of filters may be combined. As the pore diameter, the nominal values form filter manufacturers can be referred to.

Examples of the filter include filters manufactured by Nihon Pall Manufacturing Ltd., Advantec Toyo Kaisha, Ltd., Entegris Japan Co., Ltd., and KITZ MICRO FILTER CORPORATION.

Specifically, examples of the filter include P-NYLON FILTER made of polyamide (pore diameter: 0.02 m, critical surface tension: 77 mN/m, manufactured by Nihon Pall Manufacturing Ltd.), PE-CLEAN FILTER made of high-density polyethylene (pore diameter: 0.02 m, manufactured by Nihon Pall Manufacturing Ltd.), and PE-CLEAN FILTER made of high-density polyethylene (pore diameter: 0.01 μm, manufactured by Nihon Pall Manufacturing Ltd.).

Examples of the second filter include a filter formed of the same material as the first filter.

The pore diameter of the second filter may be the same as the pore diameter of the first filter.

In a case where the pore diameter of the second filter is smaller than the pore diameter of the first filter, the ratio of the pore diameter of the second filter to the pore diameter of the first filter (pore diameter of second filter/pore diameter of first filter) is preferably 0.01 to 0.99, more preferably 0.1 to 0.9, and even more preferably 0.3 to 0.9. In a case where the pore diameter of the second filter is within the above range, it is possible to remove fine foreign substances mixed in the chemical liquid.

For example, the filtering using the first filter may be performed on a mixed solution containing some of the components of the chemical liquid, the rest of the components may be mixed with the mixed solution to prepare the chemical liquid, and then the filtering using the second filter may be performed.

It is preferable that the filter to be used be subjected to a cleaning treatment before filtering the chemical liquid.

The cleaning treatment is preferably a cleaning treatment using a liquid, and more preferably a cleaning treatment using a liquid containing the chemical liquid and the components contained in the chemical liquid.

The temperature of the chemical liquid during filtering is preferably equal to or lower than room temperature (25° C.), more preferably 23° C. or lower, and even more preferably 20° C. or lower. The lower limit thereof is preferably 0° C. or higher, more preferably 5° C. or higher, and even more preferably 10° C. or higher.

In a case where the chemical liquid is at the above temperature, the amount of foreign substance particles and/or impurities contained in the chemical liquid is reduced. Therefore, filtering can be more efficiently performed.

<Diluting Step>

The chemical liquid may be used as a chemical liquid that is diluted through a diluting step of diluting with a diluent such as water (diluted chemical liquid).

Note that the diluted chemical liquid is also a form of the chemical liquid according to an embodiment of the present invention as long as the requirements of the present invention are satisfied.

The dilution factor of the chemical liquid in the diluting step may be appropriately adjusted according to the type and content of each component. The ratio of the diluted chemical liquid to the undiluted chemical liquid (dilution factor) is preferably 10 to 10,000, more preferably 20 to 3,000, and even more preferably 50 to 1,000, in terms of a mass ratio or a volume ratio (volume ratio at 23° C.).

It is also possible for a chemical liquid (diluted chemical liquid) to be suitably put to practical use, the chemical liquid containing components in amounts obtained by dividing the suitable contents of components (excluding water) contained in the aforementioned chemical liquid by the dilution factor (for example, 100) in the above range.

In other words, the suitable contents of components (excluding water) with respect to the total mass of the diluted chemical liquid are amounts obtained, for example, by dividing the amounts described as suitable contents of components with respect to the total mass of the chemical liquid (undiluted chemical liquid) by the dilution factor (for example, 100) in the above range.

A change in pH before and after dilution (a difference between the pH of the undiluted chemical liquid and the pH of the diluted chemical liquid) is preferably 2.0 or less, more preferably 1.8 or less, and even more preferably 1.5 or less.

It is preferable that the pH of the undiluted chemical liquid and the pH of the diluted chemical liquid be each in the aforementioned suitable aspect.

Specifically, the method of diluting step of diluting the chemical liquid may be performed based on the chemical liquid preparation step described above. The stirring method used in the diluting step may also be performed using known stirring devices exemplified above regarding the chemical liquid preparation step.

<Electricity Removing Step>

The manufacturing method of the chemical liquid may further include an electricity removing step of removing electricity of the chemical liquid.

It is preferable that each step in the manufacturing method of the chemical liquid be performed in a clean room.

It is preferable that the clean room meets the 14644-1 clean room standard. The clean room preferably meets any of international organization of standardization (ISO) class 1, ISO class 2, ISO class 3, or ISO class 4, more preferably meets ISO class 1 or ISO class 2, and even more preferably meets ISO class 1.

<Container>

As a container for accommodating the chemical liquid, for example, a known container can be used.

It is preferable to use a container for semiconductors which has a high internal cleanliness and is unlikely to cause elution of impurities.

Examples of the container include a “CLEAN BOTTLE” series manufactured by AICELLO CORPORATION, and “PURE BOTTLE” (manufactured by KODAMA PLASTICS Co., Ltd). In addition, in view of preventing the mixing of impurities into the raw materials and the chemical liquid (contamination), it is also preferable to use a multi-layer container with interior wall having a six-layer structure consisting of six types of resins or a multi-layer container with interior wall having a seven-layer structure consisting of seven types of resins.

Examples of the multi-layer container include the containers described in JP2015-123351A, and what are described in the document are incorporated into the present specification.

Examples of materials of the interior wall of the container include at least one first resin selected from the group consisting of a polyethylene resin, a polypropylene resin, and a polyethylene-polypropylene resin, a second resin different from the first resin, and a metal such as stainless steel, HASTELLOY, INCONEL, or MONEL. Furthermore, the interior wall of the container is preferably formed of or coated with the above materials.

As the second resin, a fluorine-based resin (perfluororesin) is preferable.

In a case where the fluorine-based resin is used, it is possible to suppress the elution of an ethylene or propylene oligomer.

Examples of the aforementioned container include a FluoroPure PFA composite drum (manufactured by Entegris, Inc.) and the containers described on page 4 of JP1991-502677A (JP-H03-502677A), page 3 of WO2004/016526A, and pages 9 and 16 of WO99/046309A.

As the Interior wall of the container, in addition to the aforementioned fluorine-based resin, quartz and a metal material finished up with electropolishing (electropolished metal material) are also preferable.

As the metal material used for the electropolished metal material, a metal material is preferable which contains at least one element selected from the group consisting of chromium (Cr) and nickel (Ni) and in which the total content of Cr and Ni is more than 25% by mass with respect to the total mass of the metal material. Examples of the metal material include stainless steel and a Ni—Cr alloy.

The total content of Cr and Ni in the metal material with respect to the total mass of the metal material is preferably 25% by mass or more, and more preferably 30% by mass or more. The upper limit thereof is preferably 90% by mass or less with respect to the total mass of the metal material.

Examples of the stainless steel include known stainless steel.

Particularly, stainless steel with a Ni content of 8% by mass or more is preferable, and austenite-based stainless steel with a Ni content of 8% by mass or more is more preferable.

Examples of the austenite-based stainless steel include Steel Use Stainless (SUS) 304 (Ni content: 8% by mass, Cr content: 18% by mass), SUS304L (Ni content: 9% by mass, Cr content: 18% by mass), SUS316 (Ni content: 10% by mass, Cr content: 16% by mass), and SUS316L (Ni content: 12% by mass, Cr content: 16% by mass).

Examples of the Ni—Cr alloy include known Ni—Cr alloys.

Particularly, a Ni—Cr alloy with a Ni content of 40% to 75% by mass and a Cr content of 1% to 30% by mass is preferable.

Examples of the Ni—Cr alloy include HASTELLOY, MONEL, and INCONEL.

Specifically, examples thereof include HASTELLOY C-276 (Ni content: 63% by mass, Cr content: 16% by mass), HASTELLOY C (Ni content: 60% by mass, Cr content: 17% by mass), and HASTELLOY C-22 (Ni content: 61% by mass, Cr content: 22% by mass).

As necessary, the Ni—Cr alloy may further contain boron, silicon, tungsten, molybdenum, copper, and cobalt, in addition to the aforementioned alloy.

Examples of the method of electropolishing the metal material include known methods.

Specifically, examples thereof include the methods described in paragraphs “0011” to “0014” of JP2015-227501A and in paragraphs “0036” to “0042” of JP2008-264929A, and what are described in these paragraphs are incorporated into the present specification.

Presumably, in a case where the metal material is electropolished, the chromium content in a passive layer on the surface thereof may is higher than the chromium content in the parent phase.

Presumably, therefore, metal elements are unlikely to be discharged into the chemical liquid from the interior wall coated with the electropolished metal material, which may make it possible to obtain a chemical liquid in which the content of a specific metal element is reduced.

It is preferable that the metal material have undergone buffing.

Examples of the buffing method include known methods.

The size of abrasive grains used for finishing the buffing is preferably #400 or less because such grains make it easy to further reduce the surface asperity of the metal material. The buffing is preferably performed before the electropolishing.

One of the multistage buffing carried out by changing the size or the like of abrasive grains, acid pickling, magnetorheological finishing, and the like or a combination of two or more of these may be performed on the metal material.

It is preferable that the container be cleaned out before being filled with the chemical liquid.

The liquid to be used for cleaning can be appropriately selected depending on the use, and is preferably a liquid containing at least one of the aforementioned chemical liquid or the component added to the chemical liquid.

In view of preventing changes in the components of the chemical liquid during storage, the container may be cleaned out by purging with an inert gas (such as nitrogen or argon) having a purity of 99.99995% by volume or higher. Particularly, a gas with a low moisture content is preferable. Furthermore, the transport and storage of the container accommodating the chemical liquid may be performed at a normal temperature or at a temperature under control. Especially, in view of preventing deterioration, it is preferable to control the temperature in a range of −20 to 20° C.

[Use]

The chemical liquid is preferably used for semiconductor devices.

“For semiconductor devices” means that the chemical liquid is used in the manufacturing of semiconductor devices.

The chemical liquid can also be used in steps for manufacturing a semiconductor device. For example, the chemical liquid can be used to treat a transition metal-containing substance, an insulating film, a resist film, an anti-reflection film, etching residues, ashing residues (hereinafter, also simply called “residues”), and the like present on a substrate. The chemical liquid may also be used for treating a substrate having undergone chemical mechanical polishing.

[Object to Be Treated]

The chemical liquid is preferably used to remove an Al oxide on a substrate.

“On a substrate” includes all of the front and back surfaces, the side surfaces, and the inside of the grooves of the substrate.

Furthermore, “Al oxide on A substrate” includes an Al oxide directly disposed on a surface of the substrate and an Al oxide disposed on the substrate via another layer.

Examples of the object to be treated include an object to be treated including a substrate and an Al oxide and a specific metal oxide that are disposed on the substrate.

The Al oxide is not particularly limited as long as it is an oxide containing Al (Al atoms) and may contain other metals.

The content of Al atoms in the Al oxide with respect to the total mass of the Al oxide is preferably 10% to 70% by mass, and more preferably 20% to 60% by mass.

The specific metal oxide is a metal oxide containing at least one element selected from the group consisting of Zn, Hf, and In. Examples of the specific metal oxide include an oxide containing Zn (hereinafter, also called “Zn oxide”), an oxide containing Hf (hereinafter, also called “Hf oxide”), and an oxide containing In (hereinafter, also called “In oxide”).

The content of Zn atoms in the Zn oxide with respect to the total mass of the Zn oxide is preferably 20% to 80% by mass, and more preferably 30% to 70% by mass.

The content of Hf atoms in the Hf oxide with respect to the total mass of the Hf oxide is preferably 5% to 65% by mass, and more preferably 15% to 55% by mass.

The content of In atoms in the In oxide with respect to the total mass of the In oxide is preferably 20% to 80% by mass, and more preferably 30% to 70% by mass.

As the substrate, a semiconductor substrate is preferable.

Examples of the semiconductor substrate include a semiconductor wafer, a glass substrate for a photomask, a glass substrate for liquid crystal display, a glass substrate for plasma display, a substrate for field emission display (FED), a substrate for an optical disk, a substrate for a magnetic disk, and a substrate for a magneto-optical disk.

Examples of materials constituting the semiconductor substrate include silicon, silicon germanium, a Group III-V compound such as GaAs, and a combination of these.

Examples of uses of the object to be treated include dynamic random access memory (DRAM), ferroelectric random access memory (FRAM, registered trademark), magnetoresistive random access memory (MRAM), phase change random access memory (PRAM), a logic circuit, and a processor.

The Al oxide on a substrate may be, for example, any of an Al oxide disposed in the form of a film, an Al oxide disposed in the form of a wiring line, and an Al oxide disposed in the form of particles.

The specific metal oxide on a substrate may be, for example, any of a metal oxide disposed in the form of a film, a metal oxide disposed in the form of a wiring line, and a metal oxide disposed in the form of particles.

In a case where the Al oxide is in the form of a film, the thickness of the Al oxide film is preferably 200 nm or less, more preferably 100 nm or less, and even more preferably 50 nm or less. The lower limit of the thickness of the Ga oxide film or the Hf oxide film is preferably 0.1 nm or more.

The Al oxide and the specific metal oxide may be disposed only on one of the main surfaces of the substrate, or may be disposed on both the main surfaces of the substrate. Furthermore, the Al oxide may be disposed on the entire main surface of the substrate, or may be disposed on a portion of the main surface of the substrate.

The object to be treated may include a layer and/or a structure as desired, in addition to the Al oxide and the specific metal oxide.

For example, a metal wire, a gate electrode, a source electrode, a drain electrode, an insulating layer, a ferromagnetic layer, and/or a non-magnetic layer may be disposed on the substrate.

The substrate may include an exposed integrated circuit structure.

Examples of the integrated circuit structure include an interconnection mechanism such as a metal wire and a dielectric material. Examples of metals and alloys used for the interconnection mechanism include aluminum, a copper-aluminum alloy, copper, titanium, tantalum, cobalt, silicon, titanium nitride, tantalum nitride, and tungsten. The substrate may include a layer of silicon oxide, silicon nitride, silicon carbide, and/or carbon-doped silicon oxide.

The size, thickness, shape, and layer structure of the substrate can be appropriately selected as desired.

[Substrate Treatment Method]

The treatment method according to an embodiment of the present invention (hereinafter, also called “the present treatment method”) includes a step A of bringing an object to be treated having a substrate and Al oxide and the specific metal oxide that are disposed on the substrate into contact with the aforementioned chemical liquid. In a case where the present treatment method is performed, the Al oxide on the substrate is selectively removed.

The object to be treated by the present treatment method is as described above.

Examples of the method of bringing the object to be treated into contact with the chemical liquid include a method of immersing the object to be treated in the chemical liquid stored in a tank, a method of spraying the chemical liquid onto the object to be treated, a method of causing the chemical liquid to flow on the object to be treated, and a method as a combination of these. Among these, the method of immersing the object to be treated in the chemical liquid is preferable.

In order to further enhance the cleaning ability of the chemical liquid, a mechanical stirring method may also be used.

Examples of the mechanical stirring method include a method of circulating the chemical liquid on an object to be treated, a method of causing the chemical liquid to flow on the object to be treated or spraying the chemical liquid onto the object to be treated, and a method of stirring the chemical liquid by using ultrasonic or megasonic waves.

The treatment time of the step A can be appropriately adjusted.

The treatment time (contact time between the chemical liquid and the object to be treated) is, for example, preferably 0.25 to 10 minutes, and more preferably 0.5 to 2 minutes.

The temperature of the chemical liquid during the treatment is preferably 20° C. to 100° C., and more preferably 40° C. to 80° C.

In the step A, a treatment may be performed in which a solvent (preferably water) is added to the chemical liquid as necessary in a state where the concentrations of the hydroxy acids, the quaternary ammonium compound, the trialkylamine and/or optional components in the chemical liquid are being measured. In a case where this treatment is performed, the concentration of components in the chemical liquid can be stably maintained in a predetermined range.

<Other Steps>

The present treatment method may have other steps in addition to the step A.

Examples of those other steps include a step of forming each structure such as a metal wire, a gate structure, a source structure, a drain structure, an insulating layer, a ferromagnetic layer and/or a non-magnetic layer (for example, layer formation, etching, chemical mechanical polishing, and modification), a step of forming resist, an exposure step and a removing step, a heat treatment step, a cleaning step, and an inspection step.

The present treatment method may be performed at any stage among the back-end process (BEOL: back end of the line), the middle process (MOL: middle of the line), and the front-end process (FEOL: front end of the line). It is preferable that the present treatment method be performed in a front-end process or a middle process.

### EXAMPLES

Hereinafter, the present invention will be more specifically described based on examples.

The materials, the amount and ratio thereof used, how to treat the materials, the treatment procedure, and the like described in the following examples can be appropriately changed as long as the gist of the present invention is maintained. Therefore, the scope of the present invention is not restricted by the following examples.

[Preparation of Chemical Liquid]

The components described in Tables 1 and 2 were prepared and mixed together according to the formulation described in Tables 1 and 2, thereby preparing chemical liquids of examples and comparative examples. The contents of various components in each chemical liquid are as described in the tables.

The amount of the quaternary ammonium compound was adjusted such that the pH shown in the table was achieved. Water is the remainder other than the various components shown in the tables.

All of those used as the various components shown in Tables 1 and 2 were substances classified as a semiconductor grade or classified as high-purity grade equivalent to the semiconductor grade.

The concentrations of a Ti metal component and a Co metal component in each chemical liquid were appropriately adjusted by adding these components to the chemical liquid or by performing a filtering treatment on the chemical liquid, such that the concentrations shown in the tables that will be described later were achieved.

<Components>

The components described in the following tables are as below.

(Hydroxy Acids)
Citric acid
Lactic acid
Tartaric acid
Glyceric acid
Glycolic acid

(Quaternary Ammonium Compound)
TMAH: Tetramethylammonium hydroxide
ETMAH: ethyltrimethylammonium hydroxide
DEDMAH: diethyldimethylammonium hydroxide
TEMAH: triethylmethylammonium hydroxide
TEAH: tetraethylammonium hydroxide
TBAH: tetrabutylammonium hydroxide

(Trialkylamine)
Trimethylamine
Diethylmethylamine
Triethylamine
Tributylamine

(Other Components)
Xanthine
Adenine
Imidazole
Uric acid
N-methyldiethanolamine
Hydroxyamine
N,N-diethylhydroxyamine
Ascorbic acid
Pyrogallol
PMDETA: N,N,N′,N″,N″-pentamethyldiethylenetriamine
DMAMP: 2-(dimethylamino)-2-methyl-1-propanol

(Water)
Ultrapure water

[Evaluation]

[Measurement of Ti and Co Contents]

The contents of Ti and Co contained in the chemical liquid were measured under the following measurement conditions.

The chemical liquids of examples and comparative examples were measured using an Agilent 8800 triple quadrupole ICP-MS (for semiconductor analysis, option #200).

(Measurement Conditions)

To measure the chemical liquids of examples and comparative examples, a quartz torch, a coaxial perfluoroalkoxyalkane (PFA) nebulizer (for self-suction), and a platinum interface cone were used. The measurement parameters of cool plasma conditions are as follows.
Output of Radio Frequency (RF) (W): 600
Flow rate of carrier gas (L/min): 0.7
Flow rate of makeup gas (L/min): 1
Sampling depth (mm): 18

[Etching Ability (AlOx)]

A substrate was prepared which was obtained by forming an AlOx layer on a commercially available silicon wafer (diameter: 12 inches) by the ALD method. From the substrate, a 2×2 cm chip was cut, thereby preparing a test piece. The thickness of the AlOx layer was 10 nm.

The obtained test piece was put in a container filled with the chemical liquid of each of examples and comparative examples, followed by stirring at 250 rpm. The treatment temperature was set to 50° C., and the treatment time was set to 10 seconds.

By ellipsometry (using a spectroscopic ellipsometer, Vase, manufactured by J.A. Woollam Japan), the film thickness before and after the treatment was measured. In this way, an etching rate (unit: Å/min) was calculated, and evaluation was performed based on the following standards. The average of etching rates at 5 spots was adopted (measurement conditions, measurement range: 1.2 to 2.5 eV, measurement angle: 700 and 75°).

(Evaluation Standard)
A: The etching rate of AlOx is 100 Å/min or more.
B: The etching rate of AlOx is 50 Å/min or more and less than 100 Å/min.
C: The etching rate of AlOx is 10 Å/min or more and less than 50 Å/min.
D: The etching rate of AlOx is less than 10 Å/min.

[Etching Selectivity (AlOx/ZnOx)]

A substrate was prepared which was obtained by forming a ZnOx layer on a commercially available silicon wafer (diameter: 12 inches) by the PVD method. From the substrate, a 2×2 cm chip was cut, thereby preparing a test piece. The thickness of the ZnOx layer was 10 nm.

The etching rate (unit: A/min) was also calculated for ZnOx by using the same procedure as in the evaluation of [Etching Ability (AlOx)], the ratio of the etching rate of AlOx to the etching rate of ZnOx (etching rate of AlOx/etching rate of ZnOx) was determined, and evaluation was performed based on the following standards.

(Evaluation Standard)
A: The ratio of etching rate of AlOx/ZnOx is 50 or more.
B: The ratio of etching rate of AlOx/ZnOx is 25 or more and less than 50.
C: The ratio of etching rate of AlOx/ZnOx is 10 or more and less than 25.
D: The ratio of etching rate of AlOx/ZnOx is less than 10.

[Defect Suppressiveness]

Each chemical liquid (0.5 mL) was spin-jetted to a rotating wafer which was prepared by the same procedure as in the evaluation of the ZnOx etching rate. Then, the wafer was spin-dried, the number of defects present on the wafer was counted using a wafer surface inspection device (SP-5, manufactured by KLA-Tencor Corporation), and evaluation was performed based on the following standards.

(Evaluation Standard)
A: There are substantially no defects on the wafer (the number of defects is less than 1,000).
B: There are many defects on the wafers although the number of defects is at an allowable level (the number of defects is 1,000 or more).

Each description in the tables is as follows.

The column of “Content (mol/L)” of “Hydroxy acids” shows the content (mol/L) of hydroxy acids per 1 L of the chemical liquid.

The column of “Content (ppb by mass)” of “Trialkylamine” shows the content (ppb by mass) of trialkylamine with respect to the total mass of the chemical liquid.

The column of “ppt by mass” of “Ti” or “Co” shows the content of Ti (ppt by mass) or the content of Co (ppt by mass) with respect to the total mass of the chemical liquid.

The column of “A/H” shows the mass ratio of the content of the trialkylamine to the content of the hydroxy acids (content of trialkylamine/content of hydroxy acids).

The column of “T/A” shows the mass ratio of the content of the specific metal component to the content of the trialkylamine (content of specific metal component/content of trialkylamine).

The notation “E-n” in the numerical values in the columns of “A/H” and “T/A” means “10⁻ⁿ”. n represents an integer of 1 or more. Specifically, “1.6E-05” in the column of “A/H” in Example 1 represents “1.6×10⁻⁵”.

The notation of “E+n” in the numerical values in “Content” in the column of “Other compounds” means “10ⁿ”. n represents an integer of 1 or more. Specifically, “2.0E+03” of “Content” in the column of “Other compounds” in Example 28 represents “2.0×10³”.

TABLE 1

| | | | Quaternary | Trialkylamine (A) | | |
|---|---|---|---|---|---|---|
| | Hydroxy acids (H) | | ammonium | | Content | |
| | | Content | compound | | ppb by | |
| | Type | mol/L | Type | Type | mass | A/H |
| Example 1 | Citric acid | 0.047 | TMAH | Trimethylamine | 140 | 1.6E−05 |
| Example 2 | Lactic acid | 0.047 | TMAH | Trimethylamine | 40 | 9.4E−06 |
| Example 3 | Tartaric acid | 0.047 | TMAH | Trimethylamine | 70 | 9.9E−06 |
| Example 4 | Glyceric acid | 0.047 | TMAH | Trimethylamine | 50 | 1.0E−05 |
| Example 5 | Glycolic acid | 0.047 | TMAH | Trimethylamine | 40 | 1.1E−05 |
| Example 6 | Citric acid | 0.047 | ETMAH | Trimethylamine | 160 | 1.8E−05 |
| Example 7 | Citric acid | 0.047 | DEDMAH | Diethylmethylamine | 180 | 2.0E−05 |
| Example 8 | Citric acid | 0.047 | TEMAH | Triethylamine | 2000 | 2.2E−04 |
| Example 9 | Lactic acid | 0.047 | TEAH | Triethylamine | 700 | 7.8E−05 |
| Example 10 | Lactic acid | 0.047 | TBAH | Tributylamine | 1300 | 1.4E−04 |
| Example 11 | Citric acid/ | 0.047/0.047 | TMAH | Trimethylamine | 180 | 1.4E−05 |
| | Lactic acid | | | | | |
| Example 12 | Lactic acid | 0.047 | TMAH/ETMAH | Trimethylamine | 60 | 1.4E−05 |
| Example 13 | Citric acid | 0.009 | TMAH | Trimethylamine | 30 | 1.7E−05 |
| Example 14 | Citric acid | 0.023 | TMAH | Trimethylamine | 70 | 1.6E−05 |
| Example 15 | Citric acid | 0.071 | TMAH | Trimethylamine | 210 | 1.5E−05 |
| Example 16 | Citric acid | 0.14 | TMAH | Trimethylamine | 400 | 1.5E−05 |
| Example 17 | Citric acid | 0.24 | TMAH | Trimethylamine | 600 | 1.3E−05 |
| Example 18 | Citric acid | 0.047 | TMAH | Trimethylamine | 200 | 2.2E−05 |
| Example 19 | Citric acid | 0.047 | TMAH | Trimethylamine | 2 | 2.2E−07 |
| Example 20 | Citric acid | 0.047 | TMAH | Trimethylamine | 2 | 2.2E−07 |
| Example 21 | Citric acid | 0.047 | TMAH | Trimethylamine | 200000 | 2.2E−02 |
| Example 22 | Citric acid | 0.023 | TMAH | Trimethylamine | 10000 | 2.3E−03 |
| Example 23 | Citric acid | 0.047 | TMAH | Trimethylamine | 1 | 1.1E−07 |
| Example 24 | Citric acid | 0.047 | TMAH | Trimethylamine | 0.01 | 1.1E−09 |
| Example 25 | Citric acid | 0.14 | TMAH | Trimethylamine | 4000 | 1.5E−04 |
| Example 26 | Citric acid | 0.047 | TMAH | Trimethylamine | 140 | 1.6E−05 |
| Example 27 | Citric acid | 0.047 | TMAH | Trimethylamine | 140 | 1.6E−05 |
| Comparative | Citric acid | 0.047 | TMAH | — | — | — |
| Example 1 | | | | | | |
| Comparative | — | — | TMAH | Trimethylamine | 10 | — |
| Example 2 | | | | | | |
| Comparative | Citric acid | 0.047 | — | Trimethylamine | 1 | 1.1E−07 |
| Example 3 | | | | | | |
| Comparative | Citric acid | 0.047 | TMAH | Trimethylamine | 10 | 1.1E−06 |
| Example 4 | | | | | | |

| | | Ti | Co | | | | |
|---|---|---|---|---|---|---|---|
| | | Content | Content | | Etching | Etching | |
| | | ppt by | ppt by | | ability | selectivity | Defect |
| | pH | mass | mass | T/A | (AlOX) | (AlOX/ZnOX) | suppressiveness |
| Example 1 | 12.0 | 90 | 10 | 7.1E−04 | A | A | A |
| Example 2 | 12.0 | 60 | 50 | 2.8E−03 | A | A | A |
| Example 3 | 12.0 | 70 | 20 | 1.3E−03 | A | A | A |
| Example 4 | 12.0 | 100 | 20 | 2.4E−03 | A | A | A |
| Example 5 | 12.2 | 80 | 30 | 2.8E−03 | A | B | A |
| Example 6 | 12.2 | 90 | 90 | 1.1E−03 | A | A | A |
| Example 7 | 12.2 | 60 | 40 | 5.6E−04 | A | A | A |
| Example 8 | 12.0 | 60 | 30 | 4.5E−05 | A | A | A |
| Example 9 | 12.2 | 100 | 50 | 2.1E−04 | A | A | A |
| Example 10 | 12.0 | 90 | 30 | 9.2E−05 | A | A | A |
| Example 11 | 12.0 | 70 | 60 | 7.2E−04 | A | A | A |
| Example 12 | 12.0 | 30 | 50 | 1.3E−03 | A | A | A |
| Example 13 | 12.0 | 120 | 30 | 5.0E−03 | A | B | A |
| Example 14 | 12.0 | 90 | 70 | 2.3E−03 | A | A | A |
| Example 15 | 12.0 | 100 | 80 | 8.6E−04 | A | A | A |
| Example 16 | 12.0 | 80 | 20 | 2.5E−04 | A | A | A |
| Example 17 | 12.0 | 80 | 10 | 1.5E−04 | B | B | A |
| Example 18 | 13.2 | 60 | 10 | 3.5E−04 | A | C | A |
| Example 19 | 7.3 | 40 | 30 | 3.5E−02 | C | C | A |
| Example 20 | 10.8 | 30 | 40 | 3.5E−02 | C | A | A |
| Example 21 | 12.0 | 30 | 60 | 4.5E−07 | A | A | B |
| Example 22 | 12.0 | 70 | 30 | 1.0E−05 | A | A | A |
| Example 23 | 12.0 | 7 | 3 | 1.0E−02 | A | A | A |
| Example 24 | 12.0 | 30 | 30 | 6.0 | B | A | A |
| Example 25 | 12.0 | 980000 | 20000 | 2.5E−01 | A | A | B |
| Example 26 | 12.0 | 8000 | 2000 | 2.5E−01 | A | A | B |
| Example 27 | 12.0 | 1 | <0.1 | 7.1E−06 | A | A | A |
| Comparative | 11.8 | 70 | 10 | — | D | C | — |
| Example 1 | | | | | | | |
| Comparative | 12.0 | 20 | 30 | 5.0E−03 | A | D | — |
| Example 2 | | | | | | | |
| Comparative | 2.3 | 20 | 20 | 4.0E−02 | D | D | — |
| Example 3 | | | | | | | |
| Comparative | 6.7 | 50 | 30 | 8.0E−03 | D | D | — |
| Example 4 | | | | | | | |

TABLE 2

| | | | Quaternary | Trialkylamine (A) | | | Other compounds | |
|---|---|---|---|---|---|---|---|---|
| | Hydroxy acids (H) | | ammonium | | Content | | | Content |
| | | Content | compound | | ppb by | | | ppm by |
| | Type | mol/L | Type | Type | mass | A/H | Type | mass |
| Example 28 | Tartaric acid | 0.047 | ETMAH | Trimethylamine | 70 | 9.9E−06 | Xanthine | 2.0E+03 |
| Example 29 | Tartaric acid | 0.047 | TMAH | Trimethylamine | 70 | 9.9E−06 | Adenine | 2.0E+03 |
| Example 30 | Lactic acid | 0.047 | TEAH | Triethylamine | 70 | 1.7E−05 | Imidazole | 2.0E+03 |
| Example 31 | Citric acid | 0.047 | TMAH | Trimethylamine | 70 | 7.8E−06 | Uric acid | 2.0E+03 |
| Example 32 | Lactic acid | 0.047 | TMAH | Trimethylamine | 70 | 1.7E−05 | N-methyldiethanolamine | 2.0E+03 |
| Example 33 | Lactic acid | 0.047 | TEAH | Triethylamine | 70 | 1.7E−05 | Hydroxyamine | 2.0E+03 |
| Example 34 | Citric acid | 0.047 | TMAH | Trimethylamine | 70 | 7.8E−06 | N,N-diethylhydroxyamine | 2.0E+03 |
| Example 35 | Tartaric acid | 0.047 | ETMAH | Trimethylamine | 70 | 9.9E−06 | Ascorbic acid | 2.0E+03 |
| Example 36 | Tartaric acid | 0.047 | ETMAH | Trimethylamine | 70 | 9.9E−06 | Pyrogallol | 2.0E+03 |
| Example 37 | Tartaric acid | 0.047 | ETMAH | Trimethylamine | 70 | 9.9E−06 | PMDETA | 1.5E+04 |
| Example 38 | Tartaric acid | 0.047 | ETMAH | Trimethylamine | 70 | 9.9E−06 | DMAMP | 1.0E+04 |

| | | Ti | Co | | | | |
|---|---|---|---|---|---|---|---|
| | | Content | Content | | Etching | Etching | |
| | | ppt by | ppt by | | ability | selectivity | Defect |
| | pH | mass | mass | T/A | (AlOX) | (AlOX/ZnOX) | suppressiveness |
| Example 28 | 13.2 | 70 | 20 | 1.3E−03 | A | A | A |
| Example 29 | 11.3 | 90 | 150 | 3.4E−03 | A | A | A |
| Example 30 | 11.4 | 110 | 20 | 1.9E−03 | A | A | A |
| Example 31 | 11.4 | 70 | 100 | 2.4E−03 | A | A | A |
| Example 32 | 11.7 | 70 | 300 | 5.3E−03 | A | A | A |
| Example 33 | 12.5 | 400 | 210 | 8.7E−03 | A | A | A |
| Example 34 | 13.1 | 540 | 100 | 9.1E−03 | A | A | A |
| Example 35 | 11.7 | 70 | 120 | 2.7E−03 | A | A | A |
| Example 36 | 11.4 | 100 | 100 | 2.9E−03 | A | A | A |
| Example 37 | 11.4 | 100 | 100 | 2.9E−03 | A | A | A |
| Example 38 | 11.4 | 100 | 100 | 2.9E−03 | A | A | A |

From the results in Tables 1 and 2, it has been confirmed that the chemical liquid has an excellent etching ability for an Al oxide on a substrate and excellent etching selectivity between an Al oxide and a specific metal oxide.

It has been confirmed that the etching ability is further improved in a case where the content of the trialkylamine is 100 ppt by mass to 200 ppm by mass with respect to the total mass of the chemical liquid, and that the etching ability for an Al oxide and defect suppressiveness are further improved in a case where the content of the trialkylamine is 100 ppt by mass to 100 ppm by mass with respect to the total mass of the chemical liquid (comparison between Example 1 and Examples 21 to 24). Furthermore, through the same comparison, it has been confirmed that the etching ability is further improved in a case where the mass ratio of the content of the trialkylamine to the content of the hydroxy acids (content of trialkylamine/content of hydroxy acids) is 1.0×10⁻⁸ to 0.1, and that the etching ability for an Al oxide and defect suppressiveness are further improved in a case where the mass ratio is 1.0×10⁻⁸ to 0.01.

It has been confirmed that defect suppressiveness is further improved in a case where the content of the specific metal component is 0.1 ppt by mass to 0.1 ppm by mass with respect to the total mass of the chemical liquid (comparison between Examples 1 and the like and Examples 25 to 27). Furthermore, through the same comparison, it has been confirmed that the etching ability is further improved in a case where the mass ratio of the content of the specific metal component to the content of the trialkylamine (content of specific metal component/content of trialkylamine) is 1.0×10⁻⁸ to 1.0, and that defect suppressiveness is further improved in a case where the mass ratio is 1.0×10⁻⁶ to 0.1 (comparison between Example 1 and Examples 21 to 27).

It has been confirmed that etching selectivity is further improved in a case where the hydroxy acids include at least one compound selected from the group consisting of citric acid, lactic acid, tartaric acid, glyceric acid, and salts thereof (comparison of Examples 1 to 5).

It has been confirmed that the etching ability is further improved in a case where the content of the hydroxy acids is 0.001 to 0.20 mol/L per 1 L of the chemical liquid, and that etching selectivity is further improved in a case where the content of the hydroxy acids is 0.01 to 0.20 mol/L per 1 L of the chemical liquid (comparison between Example 1 and Examples 13 to 17).

It has been confirmed that the effect of the present invention is further improved in a case where the pH of the chemical liquid is 7.5 to 14.0, and even further improved in a case where the pH of the chemical liquid is 11.0 to 13.0 (comparison between Example 1 and Examples 18 to 20).

A chemical liquid was prepared in the same manner as in Example 19, except that trimethylamine was changed to a mixture of triethylamine and diethylmethylamine (6:4 in terms of mass ratio) in Example 19. As a result of evaluating the obtained chemical liquid in the same manner as in Example 19, the same result as in Example 19 was obtained except that the etching ability changed from C to B.

A chemical liquid was prepared in the same manner as in Example 2, except that lactic acid was changed to serine (hydroxyamino acid) in Example 2. As a result of evaluating the obtained chemical liquid in the same manner as in Example 2, the same result as in Example 2 was obtained.

What is claimed is:

1. A chemical liquid comprising:
at least one hydroxy acid selected from the group consisting of a hydroxy acid and a salt thereof;
a quaternary ammonium compound;
a trialkylamine; and
water,
wherein the chemical liquid is alkaline.

2. The chemical liquid according to claim 1,
wherein a content of the trialkylamine is 100 ppt by mass to 200 ppm by mass with respect to a total mass of the chemical liquid.

3. The chemical liquid according to claim 1,
wherein a content of the trialkylamine is 100 ppt by mass to 100 ppm by mass with respect to a total mass of the chemical liquid.

4. The chemical liquid according to claim 1,
wherein a mass ratio of a content of the trialkylamine to a content of the hydroxy acids is 1.0×10⁻⁸ to 0.1.

5. The chemical liquid according to claim 1,
wherein a mass ratio of a content of the trialkylamine to a content of the hydroxy acids is 1.0×10⁻⁸ to 0.01.

6. The chemical liquid according to claim 1, further comprising:
at least one metal component selected from the group consisting of Co and Ti.

7. The chemical liquid according to claim 6,
wherein a content of the metal component is 0.1 ppt by mass to 0.1 ppm by mass with respect to a total mass of the chemical liquid.

8. The chemical liquid according to claim 6,
wherein a mass ratio of a content of the metal component to a content of the trialkylamine is 1.0×10⁻⁸ to 1.0.

9. The chemical liquid according to claim 6,
wherein a mass ratio of a content of the metal component to a content of the trialkylamine is 1.0×10⁻⁶ to 0.1.

10. The chemical liquid according to claim 1,
wherein the hydroxy acids include at least one compound selected from the group consisting of citric acid, lactic acid, tartaric acid, glyceric acid, and salts thereof.

11. The chemical liquid according to claim 1,
wherein a content of the hydroxy acids is 0.01 to 0.20 mol/L per 1 L of the chemical liquid.

12. The chemical liquid according to claim 1,
wherein a pH of the chemical liquid is 7.5 to 14.0.

13. The chemical liquid according to claim 1,
wherein a pH of the chemical liquid is 11.0 to 13.0.

14. The chemical liquid according to claim 1,
wherein the quaternary ammonium compound includes at least one compound selected from the group consisting of tetramethylammonium hydroxide, ethyltrimethylammonium hydroxide, diethyldimethylammonium hydroxide, triethylmethylammonium hydroxide, tetraethylammonium hydroxide, and tetrabutylammonium hydroxide.

15. The chemical liquid according to claim 1, further comprising:
a nitrogen-containing aromatic ring compound.

16. The chemical liquid according to claim 1, further comprising:
an alkanolamine.

17. The chemical liquid according to claim 1, further comprising:
at least one compound selected from the group consisting of hydroxyamine, diethylhydroxyamine, ascorbic acid, pyrocatechol, and pyrogallol.

18. The chemical liquid according to claim 1, further comprising:
a tertiary amine compound other than the trialkylamine.

19. The chemical liquid according to claim 1,
wherein the chemical liquid is used for an object to be treated having a substrate, an Al-containing metal oxide that is disposed on the substrate, and a metal oxide that is disposed on the substrate and contains at least one element selected from the group consisting of Zn, Hf, and In.

20. The chemical liquid according to claim 1,
wherein the chemical liquid is used as an etchant.

21. A treatment method comprising:
a step of bringing the chemical liquid according to claim 1 into contact with an object to be treated having a substrate, an Al-containing metal oxide that is disposed on the substrate, and a metal oxide that is disposed on the substrate and contains at least one element selected from the group consisting of Zn, Hf, and In.

22. The treatment method according to claim 21,
wherein a temperature of the chemical liquid is 40° C. to 80° C.
